(19) United States
(12) Patent Application Publication
(10) Pub. No.: US 2013/0211752 A1
(43) Pub. Date: Aug. 15, 2013

(54) SOFTWARE POWER ANALYSIS

(71) Applicant: Wayne State University, (US)

(72) Inventors: Weisong SHI, Troy, MI (US); Shinan WANG, Detroit, MI (US)

(73) Assignee: WAYNE STATE UNIVERSITY, Detroit, MI (US)

(21) Appl. No.: 13/766,582

(22) Filed: Feb. 13, 2013

Related U.S. Application Data
(60) Provisional application No. 61/598,526, filed on Feb. 14, 2012.

(51) Int. Cl. G01R 21/00

(52) U.S. Cl. CPC G01R 21/00
USPC 702/61

(57) ABSTRACT

Methods and systems for providing software power analysis. In an example, a computerized method, and system for performing the method includes determining at least one performance monitoring counter value for at least one processor. A frequency of operation is determined for the processor. A power dissipation level is calculated for the processor using a computing device and the power dissipation level is provided as an output. In an example, at least one application programming interface is received. In an example, at least one application is run. In an example, a default file is generated. The default file contains at least one power model parameter and at least one estimated frequency of operation. In an example, several performance monitoring counter values are generated for at least one core in a multi-core processor. In an example, a software power analyzer control thread is executed.

### RELATED APPLICATIONS

This application claims the benefit of:

U.S. Provisional Application No. 61/598,526, filed Feb. 14, 2012, which is hereby incorporated by reference in its entirety.

### TECHNICAL FIELD

This application relates to systems and methods for software power analysis and, more particularly, to power dissipation of or to energy consumption by instructions being executed on a processor.

### BACKGROUND

As energy dissipation increasingly becomes a consideration and concern in designing new computer systems, power aware system design raises a key issue in the community of computer systems. Power awareness is important to the battery life of a portable computing device. The increasing use of computing devices in society results in an increase in electrical energy dissipation. As some forms of electricity production are not as environmentally friendly as others, the efficient use of power in computing devices can be beneficial to society and the environment. In some applications the reduction of power usage may extend hardware life.

Software contributes to the total energy dissipation of a computer system. It is useful to find out how much power has been used or dissipated by a specific software component in order to design sustainable computer systems. Energy consumption is an aspect of software design. The total energy consumption of completing a task is power accumulation over time. Power dissipation is a direct contributor to producing an energy profile.

Understanding the power dissipation behavior of a specific software/application is the key to writing power-efficient software and designing energy-efficient computer systems.

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

In an example, a method, and system for performing the method can include using two measurements to determine the power dissipation or the energy consumption for a function of a set of instructions, an instruction, or a group of instructions to be executed in a computing machine. A computing machine may have a processor to execute the instruction, the set of instructions or the function. The method can include using the frequency of the computing machine as one of the variables. The method can include executing a software instruction power analyzer control thread.

In an example, a method, and system for performing the method can include determining at least one processor performance value for at least one processor, determining a frequency of operation for the at least one processor, calculating a power dissipation level for the at least one processor using a computing device and providing the power dissipation level as an output. The method can include receiving at least one application programming interface. The method can include running at least one application. The method can include running at least one thread. The method can include generating a default file, the default file containing at least one power model parameter and at least one estimated frequency of operation. The method can include generating a plurality of performance monitoring counter values for at least one core in a multi-core processor. The method can include executing a software power analyzer control thread.

In an example, a method, and system for performing the method can include determining at least one processor performance value for a processor or a multi-core processing system, determining an operating speed of the processor, calculating a power dissipation level for the processor using a computing device, using at least two variables of the processor. The method or system can output the power dissipation level as an output. The method can include receiving at least one application programming interface. The method can include running at least one application. The method can include running at least one thread. The method can include generating a default file, the default file containing at least one power model parameter and at least one estimated frequency of operation. The method can include generating a plurality of performance monitoring counter values for at least one core in a multi-core processor. The method can include executing a software power analyzer control thread.

In an example, a method, and system for performing the method can include determining at least one performance monitoring counter value for at least one processor, determining a frequency of operation for the at least one processor, calculating a power dissipation level for the at least one processor using a computing device and providing the power dissipation level as an output. The method can include receiving at least one application programming interface. The method can include running at least one application. The method can include generating a default file, the default file containing at least one power model parameter and at least one estimated frequency of operation. The method can include generating a plurality of performance monitoring counter values for at least one core in a multi-core processor. The method can include executing a software power analyzer control thread.

In further examples, the above method steps are stored on a machine-readable medium comprising instructions, which when implemented by one or more processors perform the steps. In yet further examples, subsystems or devices can be adapted to perform the recited steps. Other features, examples, and embodiments are described below.

### BRIEF DESCRIPTION OF DRAWINGS

Embodiments are illustrated by way of example and not limitation in the figures of the accompanying drawings, in which like references indicate similar elements and in which:

FIG. 1 is a schematic view of a data processing system according to an example embodiment.

FIG. 2 is a schematic diagram of a processor monitoring system according to an example embodiment;

FIG. 3 is a table of micro-benchmarks according to an example embodiment;

FIG. 4 is a diagrammatic view of a software power analyzer according to an example embodiment;

FIG. 5 is a power usage diagram according to an example embodiment;

FIG. 6 is a table of application programming interfaces according to an example embodiment;

FIG. 7 is a flowchart of a method according to an example embodiment;

FIG. 8 is a flowchart of a method according to an example embodiment;

FIG. 9 is a table of hardware configurations for two computer systems used to test the software power analyzer according to an example embodiment;

FIG. 10 is a table of model parameters for the tested computer systems according to an example embodiment;

FIGS. 11A-11D are plots of power usage error for several benchmarks for a tested computer system according to an example embodiment;

FIG. 11E is a summary plot of the power usage error of FIGS. 11A-11D according to an example embodiment;

FIGS. 12A-12D are plots of power usage error for the several benchmarks for a tested computer system according to an example embodiment;

FIG. 12E is a summary plot of the power usage error of FIGS. 12A-12D at a frequency of 2.00 GHz according to an example embodiment;

FIG. 12F is a summary plot of the power usage error of FIGS. 12A-12D at a frequency of 1.40 GHz according to an example embodiment; and

FIGS. 13A and 13B are graphs of power versus time for both measured power and estimated or modelled power according to an example embodiment.

### DETAILED DESCRIPTION

Example methods and systems for software power analysis are described. In the following description, for purposes of explanation, numerous specific details are set forth in order to provide a thorough understanding of example embodiments. It will be evident, however, to one skilled in the art that the present invention may be practiced without these specific details.

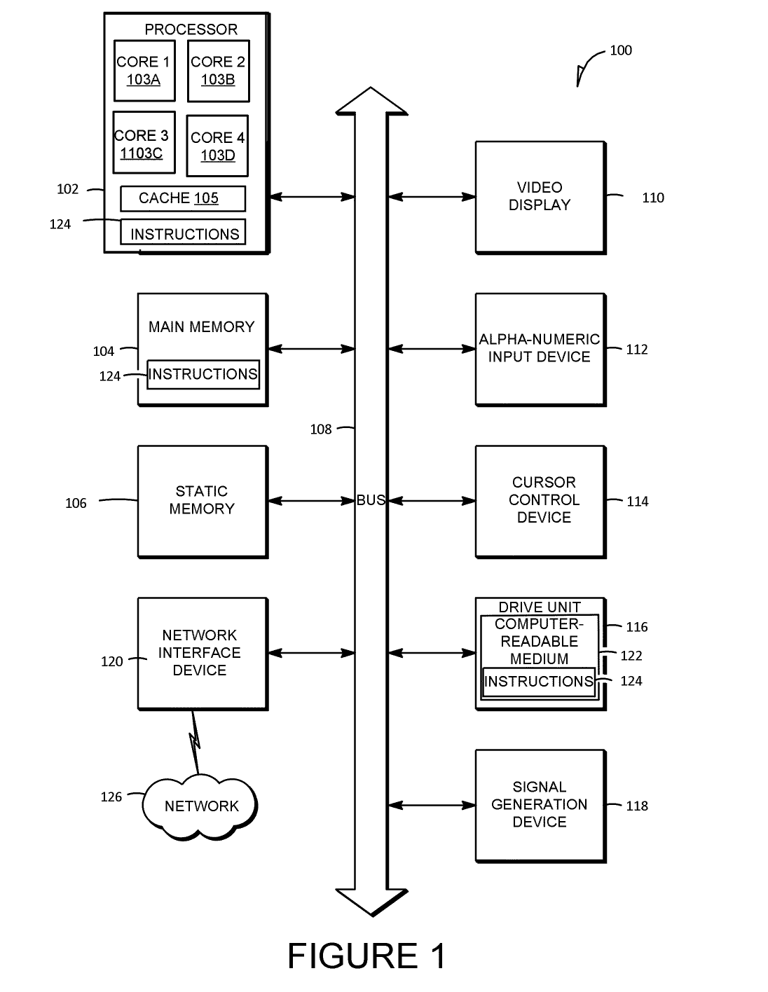

FIG. 1 illustrates a diagrammatic representation of a machine in the example form of a data processing system or computer system 100 within which a set of instructions can be executed causing the machine to perform any one or more of the methods, processes, operations, applications, or methodologies discussed herein. An example method includes determining the power dissipation of instructions for a computing machine and/or an instruction processor.

In an example embodiment, the machine operates as a standalone device or may be connected (e.g., networked) to other machines. In a networked deployment, the machine may operate in the capacity of a server or a client machine in server-client network environment, or as a peer machine in a peer-to-peer (or distributed) network environment. The machine may be a server computer, a client computer, a personal computer (PC), a tablet PC, a set-top box (STB), a Personal Digital Assistant (PDA), a cellular telephone, a web appliance, a network router, switch or bridge, or any machine capable of executing a set of instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein.

The example computer system 100 includes a processor 102 (e.g., a central processing unit (CPU) a graphics processing unit (GPU) or both), a main memory 104 and a static memory 106, which communicate with each other via a bus 108.

Processor 102 can contain several processors or cores 103A, 103B, 103C and 103D. A multi-core processor is a single computing component with two or more independent actual processors or cores which are the units that read and execute program instructions. Multiple cores can run multiple instructions at the same time increasing the overall speed for programs that can use parallel computing. Manufacturers typically integrate the cores onto a single integrated circuit die or chip. Processor 102 can also contain a cache memory 105 that cores 103A-103D can access for the storage of frequently used data.

The computer system 100 may further include a video display unit 110 (e.g., a liquid crystal display (LCD) or a cathode ray tube (CRT)). The computer system 100 also includes an alphanumeric input device 112 (e.g., a keyboard), a cursor control device 114 (e.g., a mouse), a drive unit 116, a signal generation device 118 (e.g., a speaker) and a network interface device 120.

The drive unit 116 includes a machine-readable medium 122 on which is stored one or more sets of instructions (e.g., software 124) embodying any one or more of the methodologies or functions described herein. The software 124 may also reside, completely or at least partially, within the main memory 104 and/or cache memory 105 and/or within the processor 102 or cores 103A-103D during execution thereof by the computer system 100, the main memory 104 and the processor 102 also constituting machine-readable media. The software 124 may further be transmitted or received over a network 126 via the network interface device 120.

While the machine-readable medium 122 is shown in an example embodiment to be a single medium, the term “machine-readable medium” should be taken to include a single medium or multiple media (e.g., a centralized or distributed database, and/or associated caches and servers) that store the one or more sets of instructions. The term “machine-readable medium” shall also be taken to include any medium that is capable of storing, encoding or carrying out a set of instructions for execution by the machine and that cause the machine to perform any one or more of the methodologies shown in the various embodiments of the present invention. The term “machine-readable medium” shall accordingly be taken to include, but not be limited to, solid-state memories, optical and magnetic media, and carrier wave signals.

Certain systems, apparatus, applications or processes are described herein as including a number of modules or mechanisms. A module or a mechanism may be a unit of distinct functionality that can provide information to, and receive information from, other modules. Accordingly, the described modules may be regarded as being communicatively coupled. Modules may also initiate communication with input or output devices, and can operate on a resource (e.g., a collection of information). The modules can be implemented as hardware circuitry, optical components, single or multi-processor circuits, memory circuits, software program modules and objects, firmware, and combinations thereof, as appropriate for particular implementations of various embodiments.

Aspects of the embodiments are operational with numerous other general purpose or special purpose computing environments or configurations can be used for a computing system. Examples of known computing systems, environments, and/or configurations that may be suitable for use with the embodiments include, but are not limited to, personal computers, server computers, hand-held or laptop devices, multiprocessor systems, microprocessor-based systems, set top boxes, programmable consumer electronics, network PCs, minicomputers, mainframe computers, distributed computing environments that include any of the above systems or devices, and the like. These devices can be used to compute the power dissipation as described or can be devices on which the power dissipation is measured. The power dissipation determination can be especially beneficial to portable devices with limited battery life and to devices that are part of large computing systems, e.g., server farms.

The communication systems and devices as described herein can be used with various communication standards to connect any of the hardware devices described herein. In some communication standards instructions are executed on processors, which can be dedicated processors for communication. In other examples, the processors can be processors that execute communication instructions and other instructions as loaded into the processor. Examples include the Internet, but can be any network capable of communicating data between systems. Other communication standards include a local intranet, a PAN (Personal Area Network), a LAN (Local Area Network), a WAN (Wide Area Network), a MAN (Metropolitan Area Network), a virtual private network (VPN), a storage area network (SAN), a frame relay connection, an Advanced Intelligent Network (AIN) connection, a synchronous optical network (SONET) connection, a digital T1, T3, E1 or E3 line, Digital Data Service (DDS) connection, DSL (Digital Subscriber Line) connection, an Ethernet connection, an ISDN (Integrated Services Digital Network) line, a dial-up port such as a V.90, V.34 or V.34bis analog modem connection, a cable modem, an ATM (Asynchronous Transfer Mode) connection, or an FDDI (Fiber Distributed Data Interface) or CDDI (Copper Distributed Data Interface) connection. Wireless communications can occur over a variety of wireless networks, including WAP (Wireless Application Protocol), GPRS (General Packet Radio Service), GSM (Global System for Mobile Communication), CDMA (Code Division Multiple Access) or TDMA (Time Division Multiple Access), cellular phone networks, GPS (Global Positioning System), CDPD (cellular digital packet data), RIM (Research in Motion, Limited) duplex paging network, Bluetooth radio, or an IEEE 802.11-based radio frequency network. Instructions that are used in these communication standards can be evaluated according to the power dissipation methods and systems described herein.

The power dissipation of a given computer system can be modeled in two parts, baseline power and dynamic power. The first part is baseline power which is the static power needed to maintain running of the computer system. Static power can include the power consumed by a motherboard, CPU, memory, CPU fans, and other components in the computer system. Dynamic power includes the power consumed or used by during execution of a software task. When workloads are executed on different computer systems and at different rates, the dynamic power used can vary. Other factors that can contribute to power usage can be temperatures, characteristics of workloads, and component utilizations.

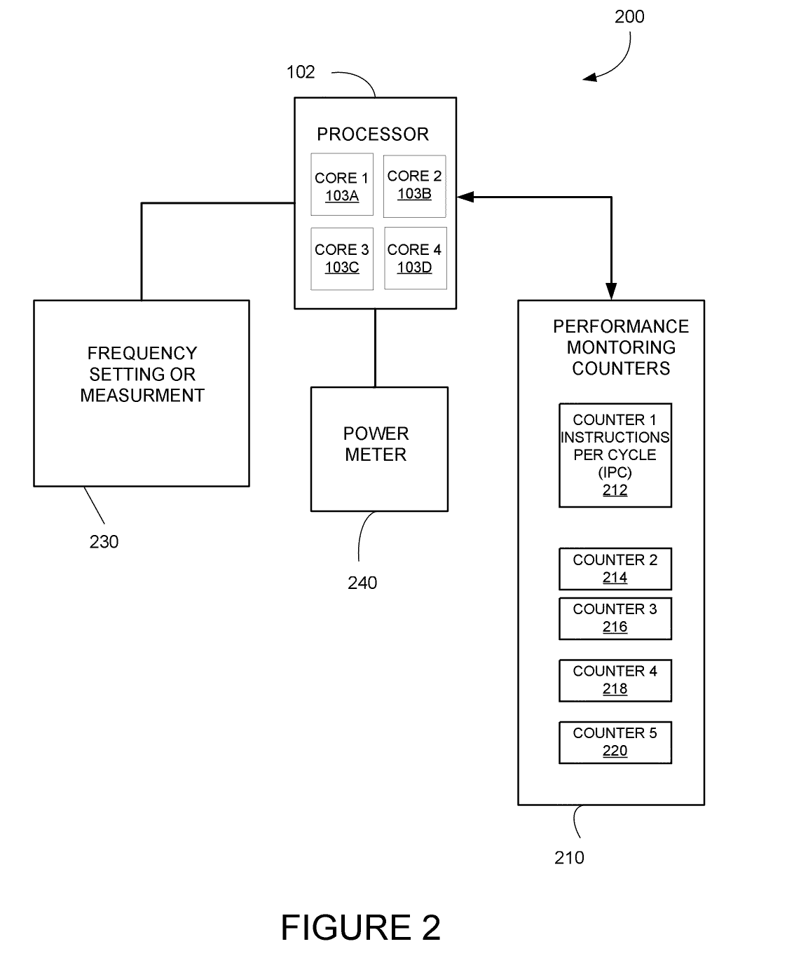

With reference to FIG. 2, a diagrammatic view of a processor monitoring system 200 is shown. Processor monitoring system 200 can include processor 102, several performance monitoring counters (PMC) or hardware counters 210 that are in communication with processor 102 and a power meter 240. Performance monitoring counters 210 can include counter 1, 212, counter 2, 214, counter 3, 216, counter 4, 218 and counter 5, 220. In other embodiments, more or fewer counters can be used. A frequency setting or measurement 230 is also in communication with processor 102. In one embodiment, frequency setting or measurement 230 can be the clock cycle frequency or rate of the processor 102 or of any one or more cores 103A-103D. In other embodiment, frequency setting or measurement 230 can be the measured operating frequency of processor 102 or of any one or more of the cores 103A-D. Power meter 240 is in communication with processor 102. Power meter 240 can measure the actual power used or consumed by processor 102 for a given period of time. In an example, performance monitoring counters 210, frequency setting or measurement 230 and power meter 240 can be internal with processor 102. In another example, power meter 240 can be an external multi-meter in electrical or electromagnetic communication with the processor 102 or any one of the processor cores 103A-103D.

A power estimation model of the dynamic power used on a multi-core processors such as processor 102 can be implemented using performance monitoring counters (PMC) 210. Performance monitoring counters 210, which may also be referred to as hardware counters, are a set of special-purpose registers built into a processor or microprocessors to store the counts of hardware-related activities within computer systems. The number of available PMCs 210 in a processor can be limited. Each PMC can be programmed with the index of an event type to be monitored, like the number of instructions completed per cycle (IPC) or the number of L1 cache reads or writes or the number of misses of an operation. Counter 1 212 is shown as determining, measuring or counting the number of instructions completed per cycle (IPC).

Utilizing a larger number of PMCs 210 to estimate power usage allows for a more detailed and accurate power model. However, collecting a large number of PMCs 210 can involve more overhead. Processors can retrieve a certain number of counters simultaneously. In an example, performance monitoring counters 210 can be multiplexed so that additional counters can be used for a one model or benchmark. For example, if counters 212-220 are multiplexed over three cycles, a total of fifteen performance monitoring counter measurements can be collected.

It is desirable for a power estimation model to have a high degree of accuracy, for the parameters of the model to be readily determined or measured and the total number of performance monitoring counters to be low to reduce multiplexing operations. Using a lower number of PMCs allows a more flexible power model. In an example, one PMC can be used. In an example, the performance monitoring counter can be the number of instructions per cycle (IPC) as tracked by counter 1 212 during processing.

Micro benchmarks can be used to test and modify a power dissipation model. Micro benchmarks are used to measure the performance of a small bit of code. In an example, 12 benchmarks can be tested on the processor in order to develop a power dissipation model.

In an example, instructions per cycle (IPC) and processor or core operation frequency can be used as a power dissipation model input or an energy dissipation model input. One issue with using IPC alone is that different micro-benchmarks can have various IPC values but similar power dissipation. For example, Floating Point Unit can execute instructions slower than Integer Arithmetic Unit with similar power dissipation. The model can be improved by analyzing more PMC values for each processor or core such as FP (floating point), INT (integer), and BPU (branch prediction unit) separately. However, it is desirable to minimize the number of PMCs used.

Power dissipation of a processor can be limited by its operating frequencies. As the IPC value becomes large or small enough, the effects of IPC on power dissipation decrease or an energy dissipation decrease. In an example, frequency can be used as the primary power usage indicator and IPC can be used as a secondary power usage indicator that tunes the estimation results obtained according to operating frequencies. Micro-benchmarks can be divided into different categories based on the IPC values, data collected and a power dissipation model generated for each category of IPC value.

The frequency of operation of processor 102 (FIG. 2) can be labeled as F. Assuming that processor 102 supports various frequencies, fi, i=1, 2, 3, . . . , n, the power dissipation information, P(fi), can be calculated for each frequency fi. Given a set of training benchmarks T with its sub benchmarks tj, j=1, 2, 3, . . . , m, executing under frequency fi, the power dissipation is denoted as P(tj, fi) respectively. P(fi) is calculated as the median of {P(t1, fi), P(t2, fi), . . . , P(tm, fi)}; therefore P(fi) is resistant to outliers statistically.

The IPC of each benchmark is represented as IPC(tj, fi). Similarly, the median IPC value of all the training benchmarks are defined as IPC(fi). The benchmarks with the median value of P(tj, fi) can also contribute to the median value of IPC(tj, fi). P(fi) and IPC(fi) are defined as a power pilot for frequency fi.

In a second step based on the power pilot, ΔP(tj, fi) is calculated as the difference between P(fi) and P(tj, fi) for each training benchmark. Similarly, ΔIPC(tj, fi) is the IPC difference of training benchmark ti to the median value.

ΔP(tj,fi)=P(tj,fi)−P(fi) (1)

ΔIPC(tj,fi)=IPC(tj,fi)−IPC(fi) (2)

ΔIPC(tj, fi) is used as model input to derive linear regression parameters, Pinct(fi) and P_{Δ}(fi) as equation (3) shows. The final predicted power dissipation model is shown in equation (4). ΔIPC(ti, fi) is changed to be the actual ΔIPC(ai, fi) before applying the model to the i th benchmark from task set a1, a2, a3, . . . , an.

ΔP(tj,fi)pret=Pinct(fi)+P_{Δ}(fi)×ΔIPC(tj,fi) (3)

P(tj,fi)pret=ΔP(tj,fi)pret+P(fi) (4)

In one example, the majority of power dissipation can be determined by P(fi), which stems from frequency characteristics forced on each training set although the regression model is applied to ΔP(tj, fi)pret. Because Pinct(fi) and P_{Δ}(fi) usually are small enough, we limit the inaccuracy from those IPC values while reserving the positive relation between most IPC values and power dissipation.

Using IPC solely can produce low accuracy when the values of IPC are either too high or too low. In order to constrict this marginal effect, the given training benchmark can be changed. First, the training set of benchmarks T is ordered with descending IPC, which yields T_{ordered}. Second, T_{ordered} is divided into three categories with respect of their IPC values. Heuristic results, based on the average accuracy provided, show that the separating points are located approximately at 0.87 and 1.86. As a result, there are three groups of benchmarks: the one with relative low IPC, T_{low}, with average normal IPC, Tₙₒᵣₘₐₗ, and with relative high IPC, T_{high}.

For each group, the same method is used to obtain P(tIPC level, fi), IPC(tIPC level, fi), Pinct (tIPC level, fi), and P_{Δ}(tIPC level, fi), where IPC level represents low, high, and normal. An accumulative approach is used for modeling multiple cores based on the assumption that each core has similar power behavior. Therefore, the single core model can be applied to each core in the system. The total power dissipation or, in some cases, energy consumption, is estimated by equation (5):

P(aj,fi)_{pret total}=Σ^{k=cores}ₖ₌₁(ΔP(aj,fi,k)pret+P(fi)) (5)

In equation (5), aj is the target benchmark and ΔP(aj, fi, k)pret is generated at the per core level because different cores might have different ΔIPC(ti, fi, k) values. Modern processors with multiple cores can support per core level PMCs. Formula (5) can be modified because P(fi) accounts for the power consumed by shared resources that should not be replicated. One example of shared resources is L2 cache. To account for shared resources, another parameter is used that can be determined at the training stage, P_{shared(k)}. In order to retrieve information on P_{shared(k)}, the training benchmarks are executed on k cores, and median values are selected as P_{shared(k)} for each k. The values of P_{shared(k)} are different, which is determined by the total number of cores utilized by a task simultaneously. The bigger k is, the larger P_{shared(k)} could be. The final formula to estimate the power dissipation of aj of a multicore processor is given by equation (6):

P(aj,fi)_{pret total}=Σ^{k=cores}ₖ₌₁(ΔP(aj,fi,k)pret+P(fi))=Σ^{k=cores}ₖ₌₁(Pinct(fi)+P_{Δ}(fi)×ΔIPC(aj,fi,k))+Σ^{k=cores}ₖ₌₁P(fi)−P_{shared(k)} (6))

The power model of equation (6) can assist in selecting the benchmarks that are used. A wide range of IPC values are covered by training benchmarks. Two margins of benchmarks can be tested with smaller or larger IPC values since it has been observed that different power behaviors affected by IPC at those ranges. In an example, an even distribution of benchmarks according to their IPC values can be used. Training benchmarks can be divided into three groups based on IPC values. It is more informative if the number of training benchmarks resides in each group equally.

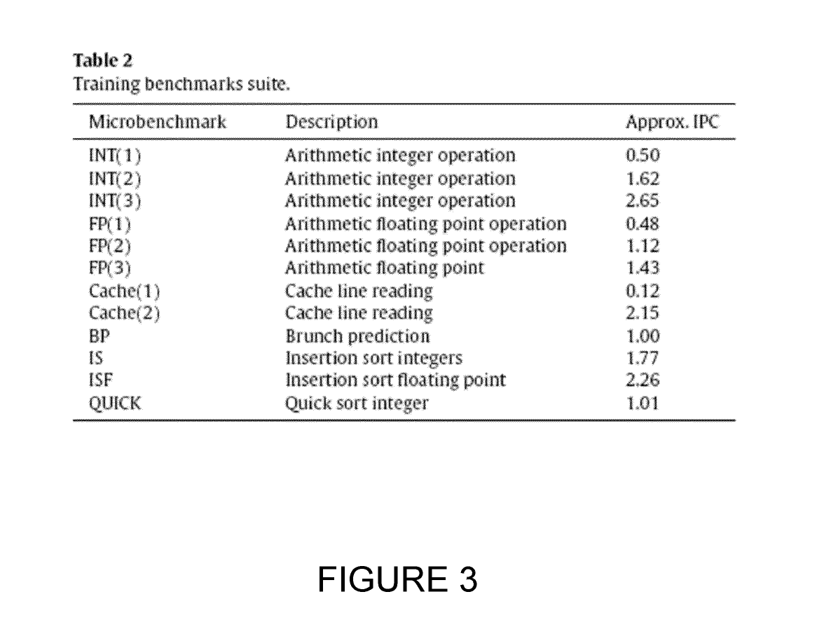

In an example, training workloads can be generated covering a sufficient variety of processor activities for a linear regression based approach. In an example, 36 benchmarks were studied to exercise various processor components, such as INT, FP, and BPU registers. Twelve benchmarks were selected covering maximum subunits, occupying a wide range of IPC values, and fairly even distributed. The twelve benchmarks utilized are shown in FIG. 3. In general, the benchmarks exercise most of the processor subunits separately. The last three benchmarks utilize several components together to form mixed benchmarks.

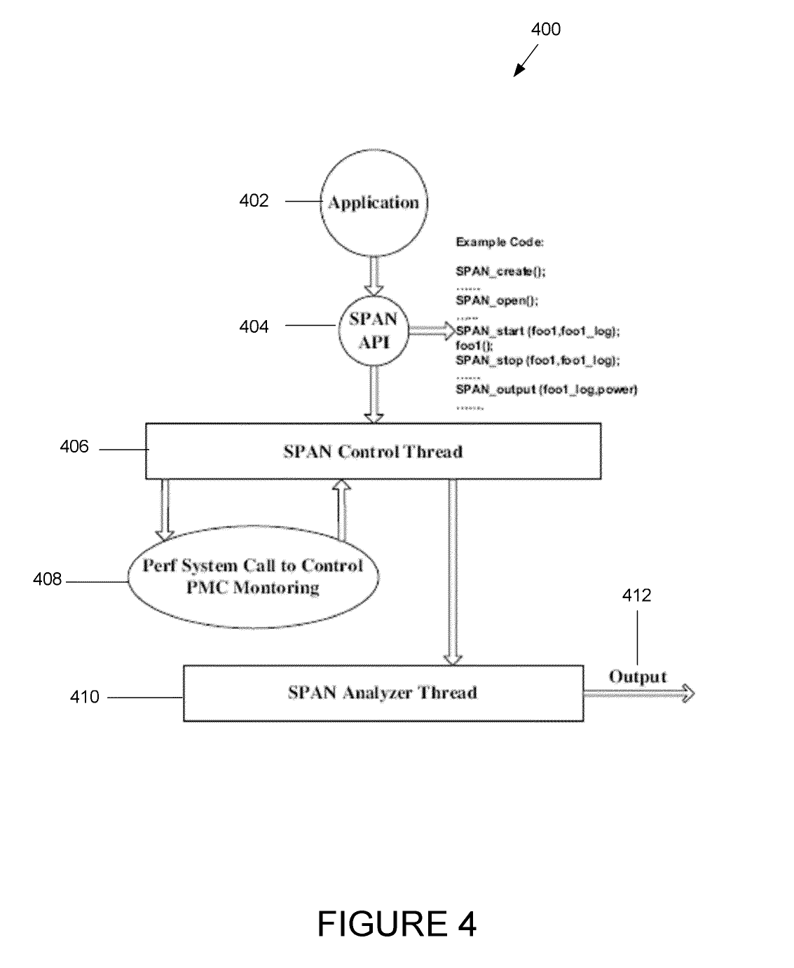

Turning now to FIG. 4, a diagrammatic view of a software power analyzer (SPAN) 400 is shown. Software power analyzer (SPAN) 400 can calculate or determine the power used or consumed when running various software programs or code. SPAN 400 can include application information 402, application programming interface (API) 404, SPAN control thread 406, system call 408 for performance monitoring counter values, SPAN analyzer thread 410 and SPAN output 412.

The application information 402 and performance monitoring counter values from system call 408 are provided as inputs to the software power analyzer. At the application level, the application information 402 and the estimation control application programming interface 404 are passed to the control thread 406 through the designed SPAN APIs 404. Utilizing the run-time PMC values by calling the system call 408, the span analyzer thread 410 applies the power model of equation (6) to estimate the power used, dissipated or consumed. A figure of estimated power dissipation or used is provided as a power usage output 412. Software power analyzer (SPAN) 400 can be implemented in software instructions 124 (FIG. 1), stored in computer readable medium 122 and executed on processor 102.

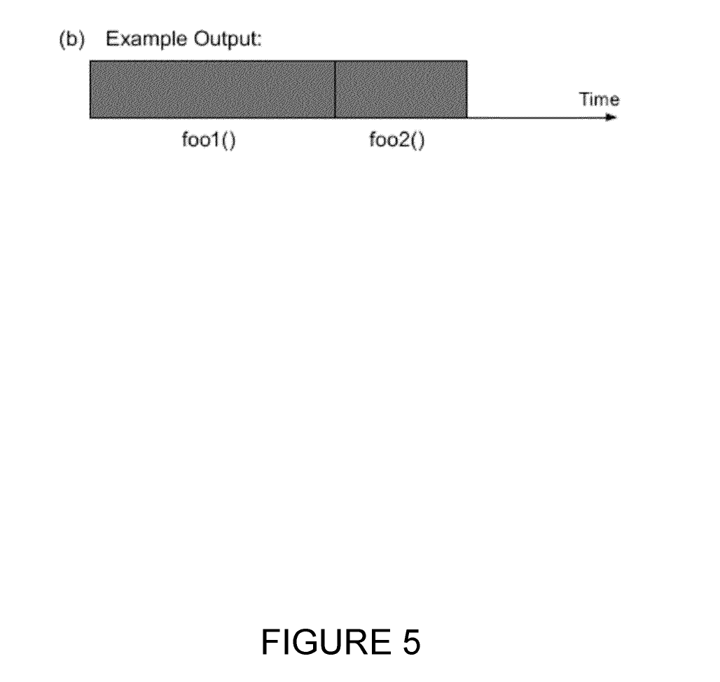

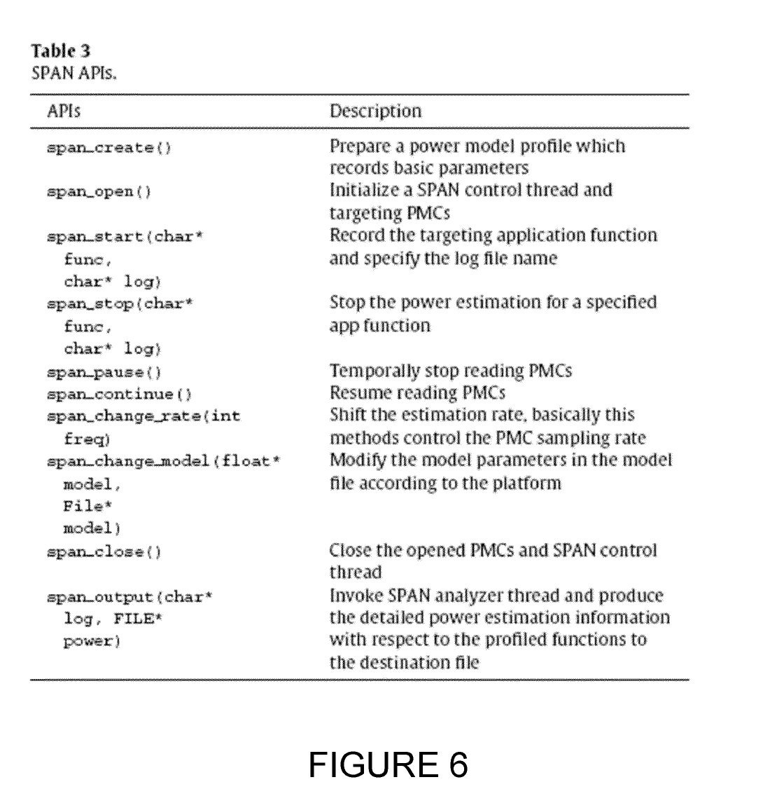

In one embodiment, power usage output 412 can be plotted with time and represented as shown in FIG. 5. FIG. 6 illustrates examples of several of the designed SPAN APIs. In an example, SPAN application programming interface 404 can be implemented in a C language library of the API of FIG. 6.

Software power analyzer 400 can provide live, real time power usage information of software applications running on processor 102 of computer system 100. Software power analyzer 400 can specify a suite of external API calls to correlate power estimation with application source codes. This is defined as source code level instrumentation. There are several advantages of using software power analyzer 400, these include lower overhead, applicability, and independence against instrumentation tools, such as binary instrumentation tools like PIN.

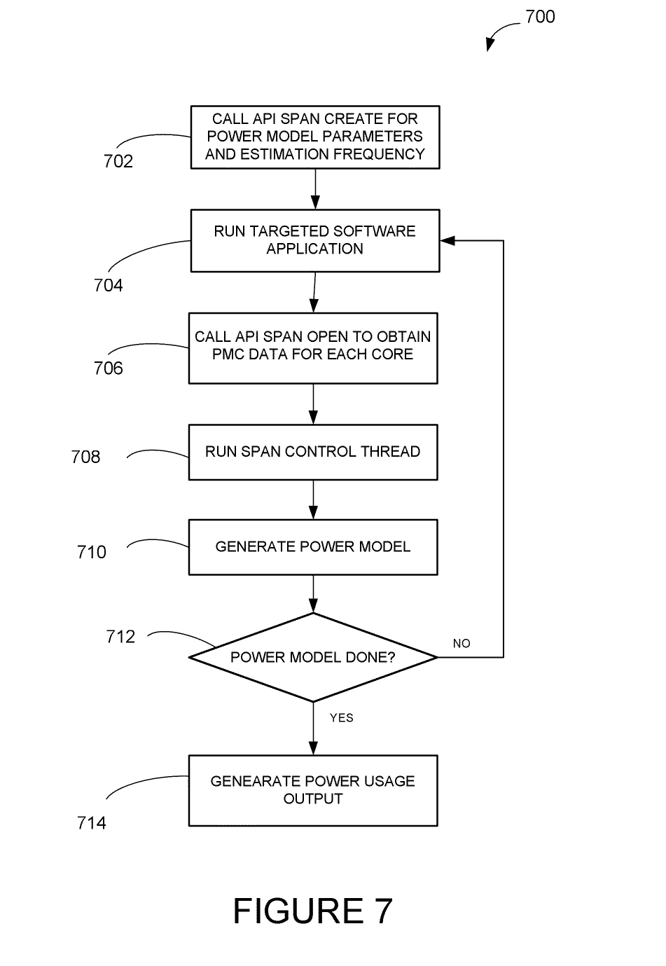

FIG. 7 illustrates one embodiment of a flow chart of a method 700 for determining power usage by a computer system executing a software program using software power analyzer 400. At step 702, the API span create is called to prepare a default file describing a set of power model parameters and an estimation frequency. In step 704, the targeted software application to determine power usage is run on processor 102 (FIG. 1). PMCs are opened for each core respectively by calling span open at step 706 in order to retrieve PMC data for each core. At step 708, the SPAN control thread is run by processor 102. The SPAN control thread stores the row PMC information and the application function information (e.g., function name and start time). The SPAN control thread is started or executed before each profiling function. The power usage model is generated at step 710.

At decision 712, it is determined if the power model is completed. If the power model is complete, method 700 proceeds to step 714 where the power usage output is generated and stored in a file. If the power model is not complete, method 700 returns to step 704 where method 700 continues to run the software application or function to collect more data and create more refined power usage models. Steps 704-712 can continue until the API span stop or span pause( ) are called.

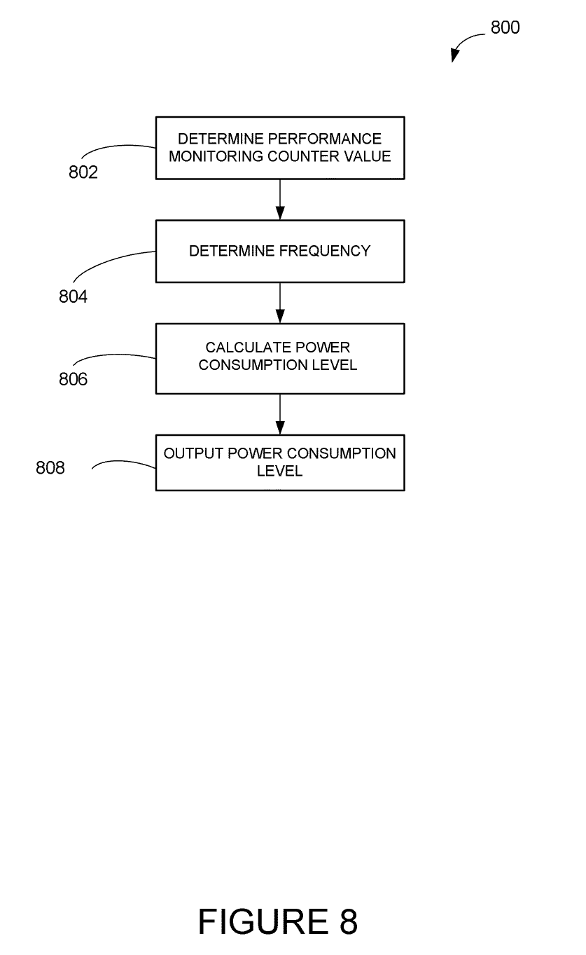

FIG. 8 illustrates one embodiment of a flow chart of a method 800 for determining power usage by a computer system executing a software program using software power analyzer 400. At step 802, the performance monitoring counter values from one or more software applications running on processor 102 (FIG. 1) are determined. The operation frequency of cores 103A-103D in processor 102 are determined in step 804. In step 806, a program routine is run on computer system 100 to calculate the power dissipation level or usage by the software application. The power dissipation level or usage is output in step 808.

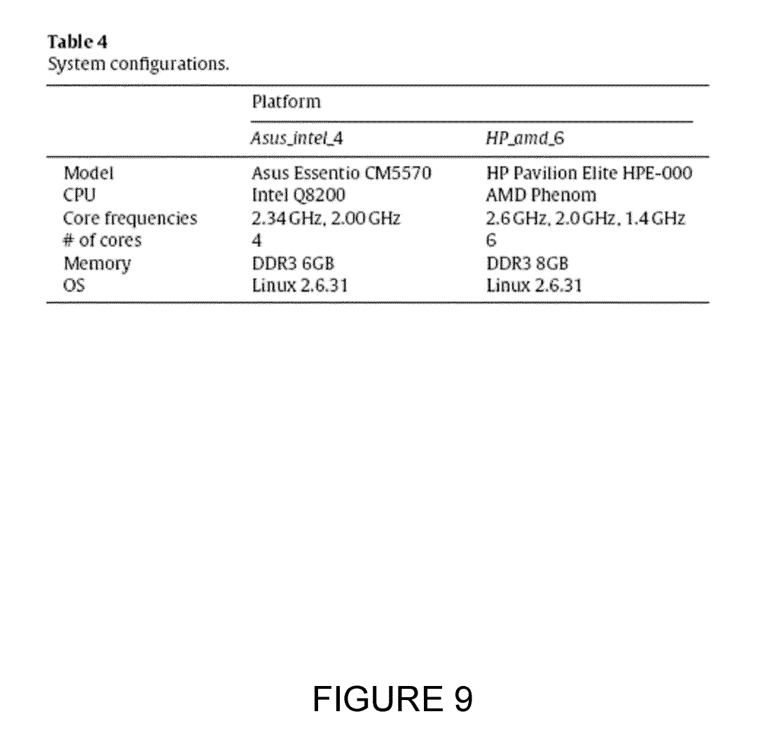

Software power analyzer 400 and methods 700 and 800 were empirically tested. The power models were evaluated on two different computer system 100 platforms, an ASUS INTEL 4 and an HP AMD 6, where 4 and 6 represent the number of cores on each processor respectively. The hardware configuration of each of the tested computer systems is shown in FIG. 9.

The power usage was generated using by the SPEC2008Cjvm benchmarks to validate the power model. Java version 1.6.0 18 was used on both platforms to launch each benchmark. The warm time is set to five (5) minutes and the iteration time is 10 minutes. The −bt option was altered to change the number of threads. The CPU affinity was set to one core during the training process originally, which will minimize CPU migrations and provide a set of more optimized model parameters. The system does not restrict CPU affinity in all of our training and evaluation process.

The PMCs values are collected using the kernel system call, NR perf event open( ), which is available in Linux kernel version 2.6.31. Leakage power becomes a non-trivial portion of the power budget on modern superscalar processors. Experimental results show that leakage current increases exponentially with the supply voltage; however, given a specific CPU frequency and supply voltage, as the input of our model, the leakage power can be assumed as fixed or constant. Therefore, leakage power is not used in the power model.

In order to minimize the temperature effect on power, after each valid run, the computer system is turned off for 10 minutes as a cooling time. The static power is measured before each execution, and the variation of the static power is less than 5%. There are small static power variations for different operating frequencies. Hardware measurements are used to collect power usage or dissipation/consumption information on the processor using power meter 240 (FIG. 2). The actual results are compared with the estimated power usage or dissipation.

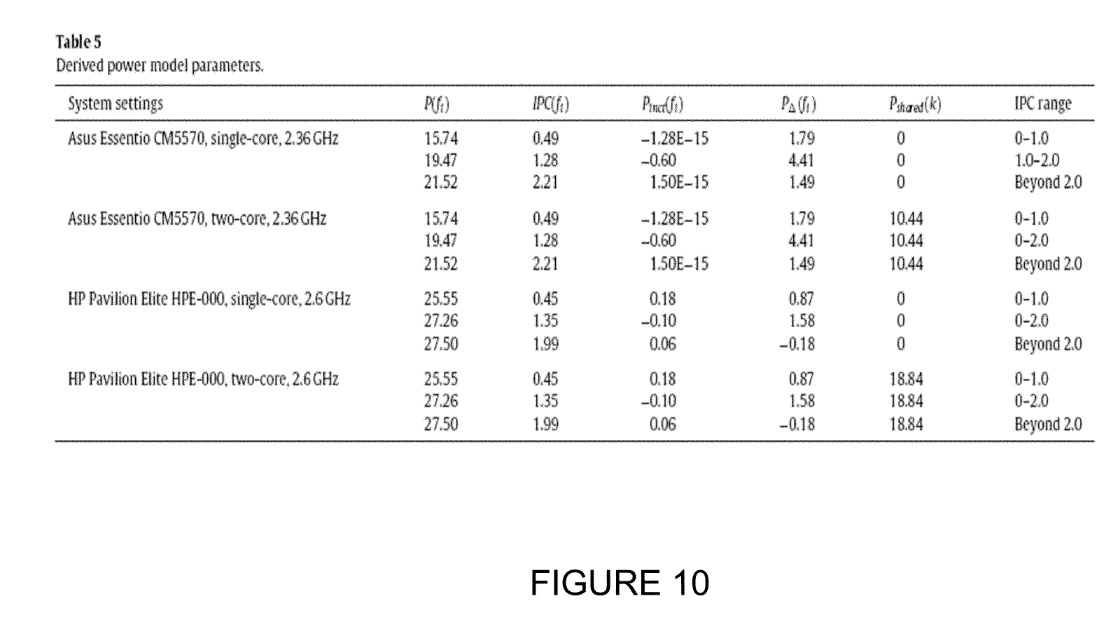

A set of model parameters are generated from the training benchmarks. Some of the detailed model parameters derived from the training process are listed in FIG. 10 for the tested computer systems. The effects of instructions per cycle (IPC) on power drop are considerable at both margins: the IPC below 1.0 and beyond 2.0. The model is evaluated in terms of accuracy to actual measurement. The SPEC2008Cjvm benchmarks with multi-threads are run on possible frequencies to collect data. The errors are reported for the whole processor.

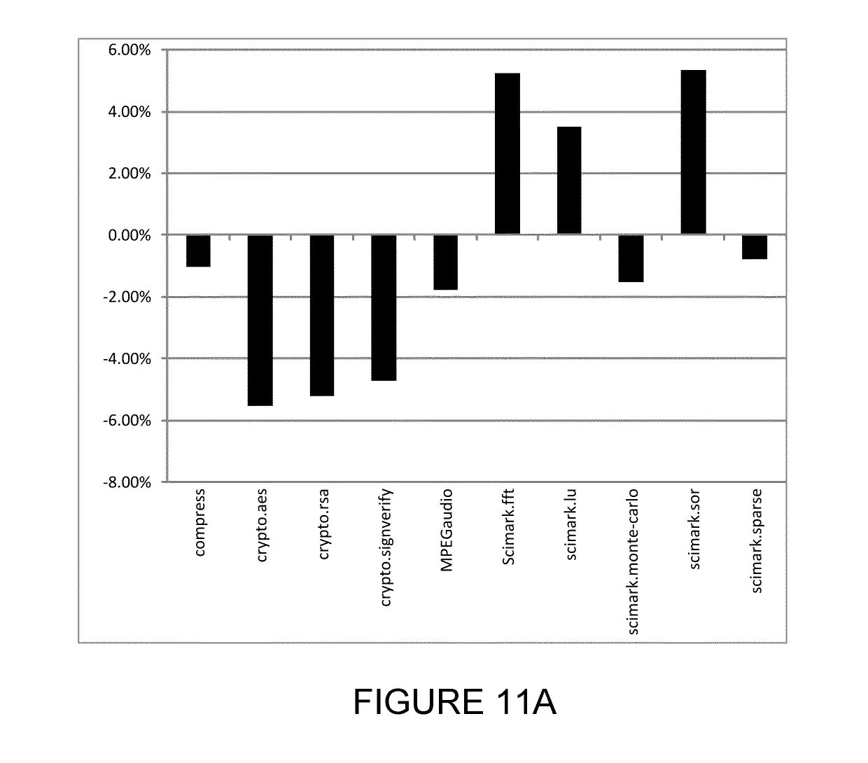

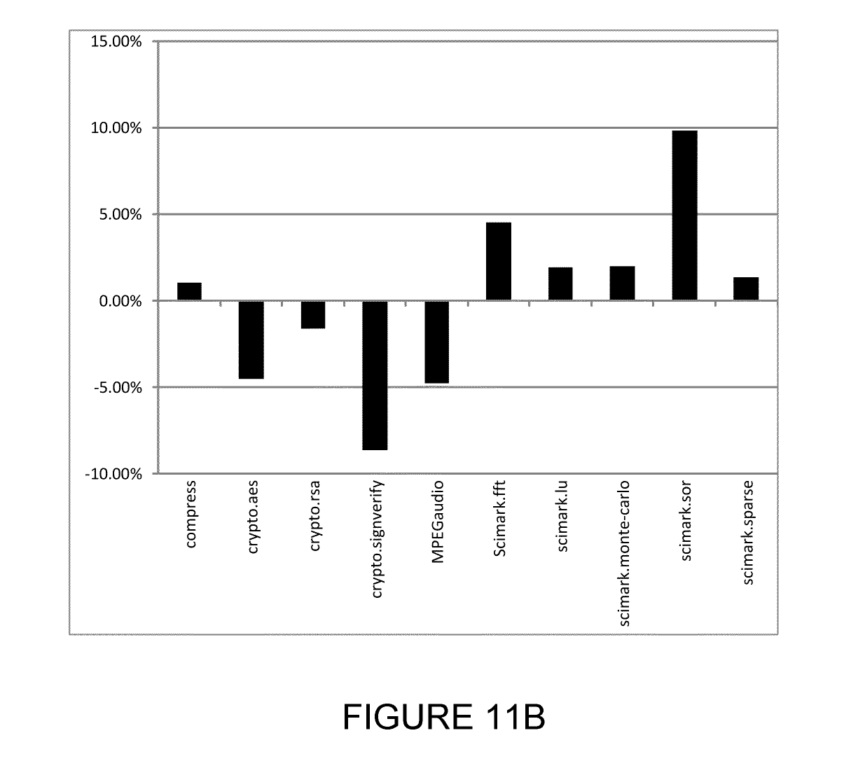

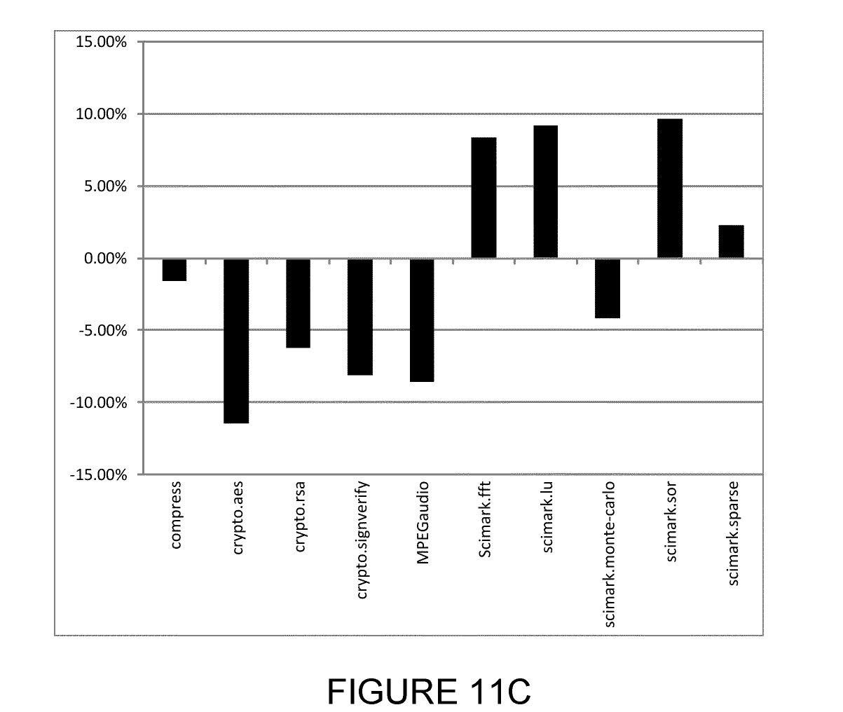

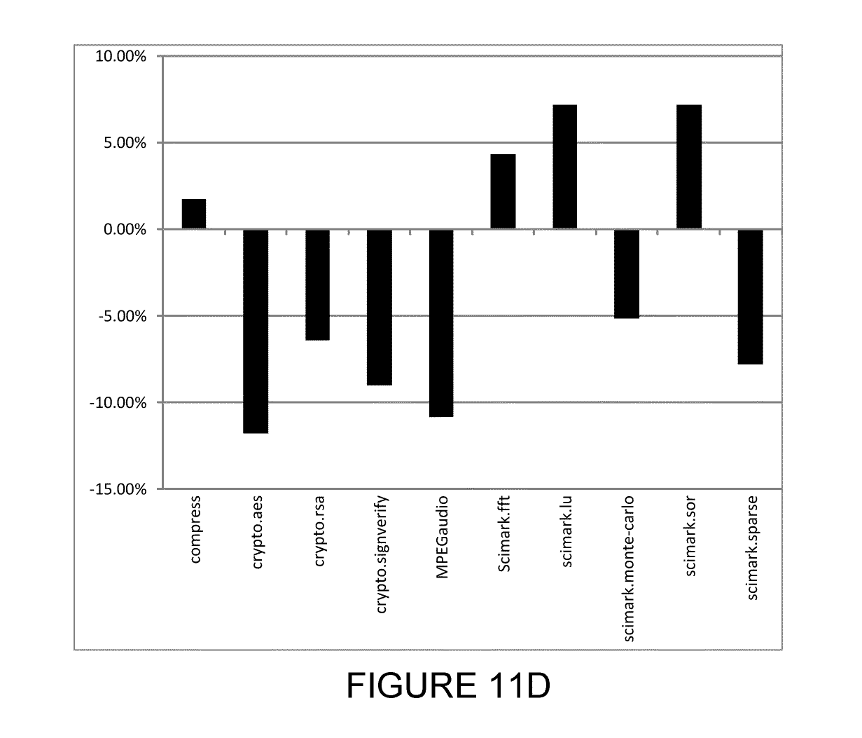

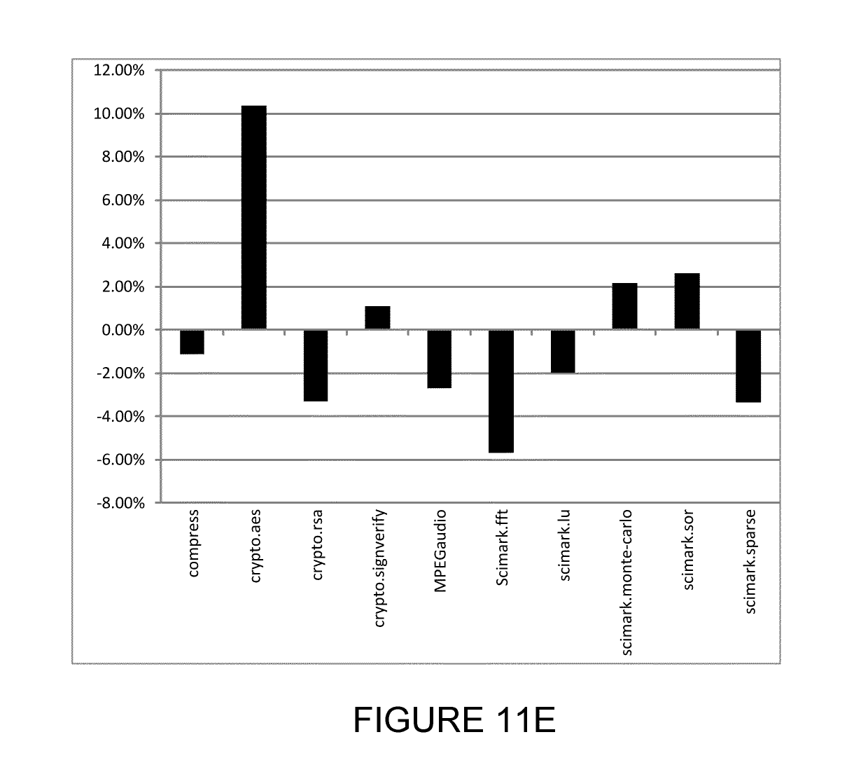

FIGS. 11A-11D show the percentage error from a single core to the maximum four cores running 10 different benchmarks on the ASUS INTEL 4 computer system. As the figures illustrate, generally, there is an incremental relationship between error rate and the number of cores. One possible reason is that the shared resource is not evaluated in a fine granularity in the power model due to limitations of the PMC data. The inter-core communications, which are another source of power usage, are be captured by the power model when one PMC is used. In an example, the power usage model achieved 5.17% absolute error rate on average, with a standard deviation of 5.40%.

FIG. 11E summarizes the estimated error at a frequency of 2.00 GHz on the ASUS INTEL 4 computer system. The model achieves a smaller error rate since the power dissipation for each benchmark decreases and falls into a narrow range, which is less unpredictable than the scenario of high frequency. The power dissipation of some particular benchmarks, such as crypto.aes, presents a low correlation coefficient to the IPC and extensive usage of other processor components, such as brunch prediction units.

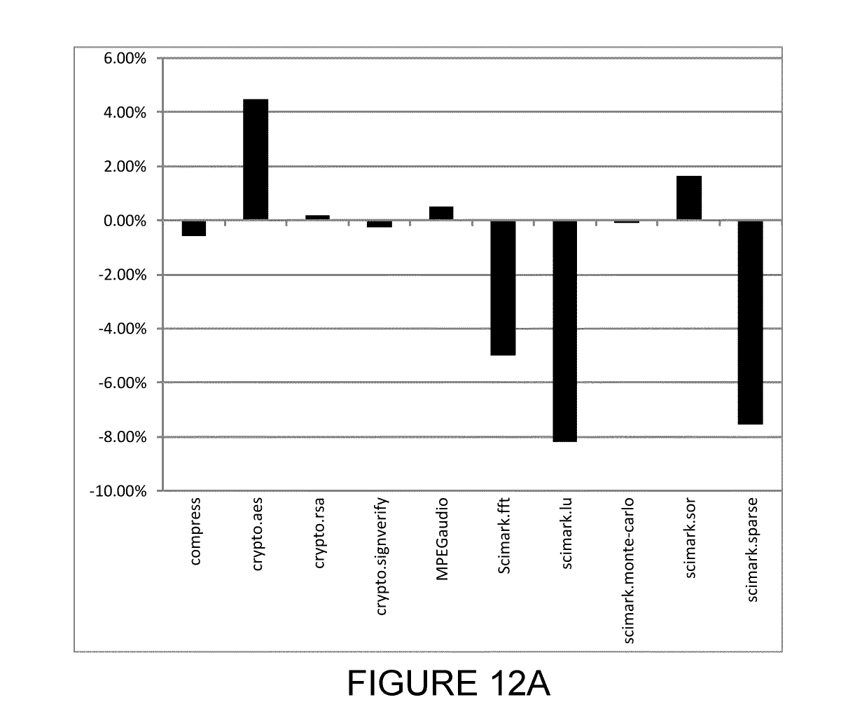

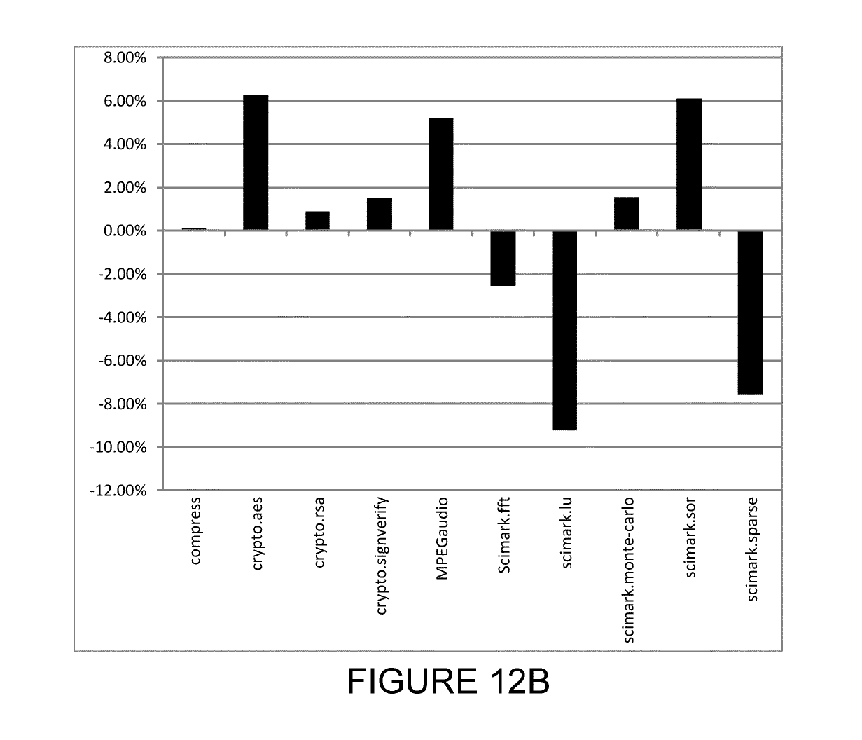

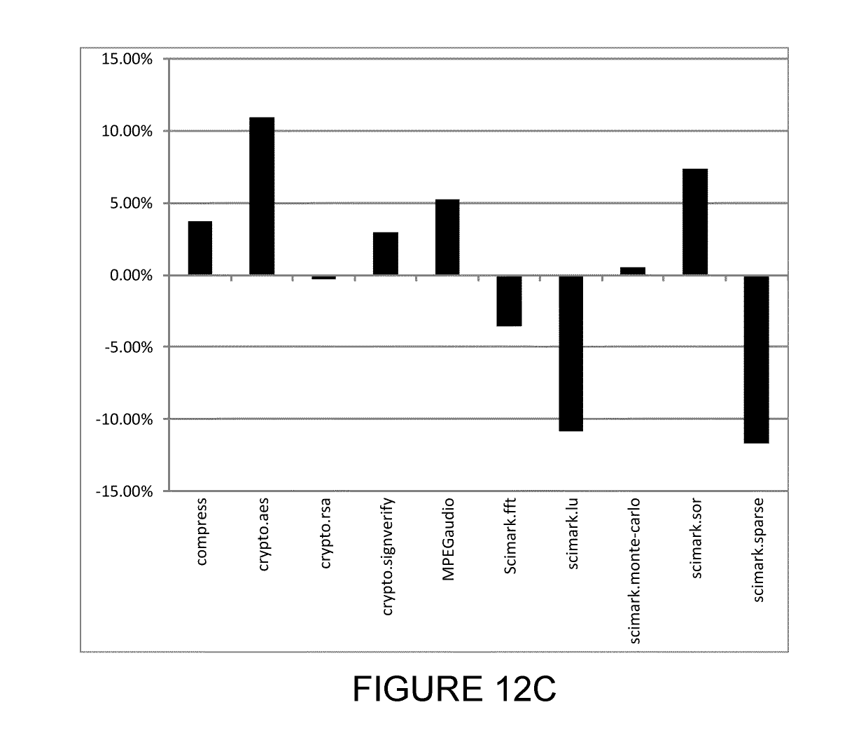

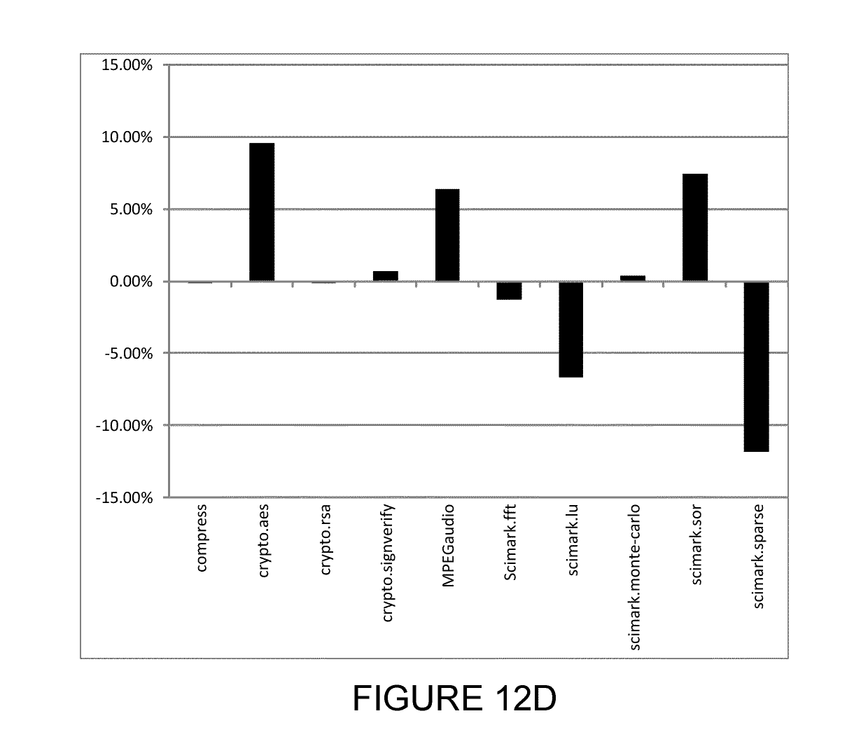

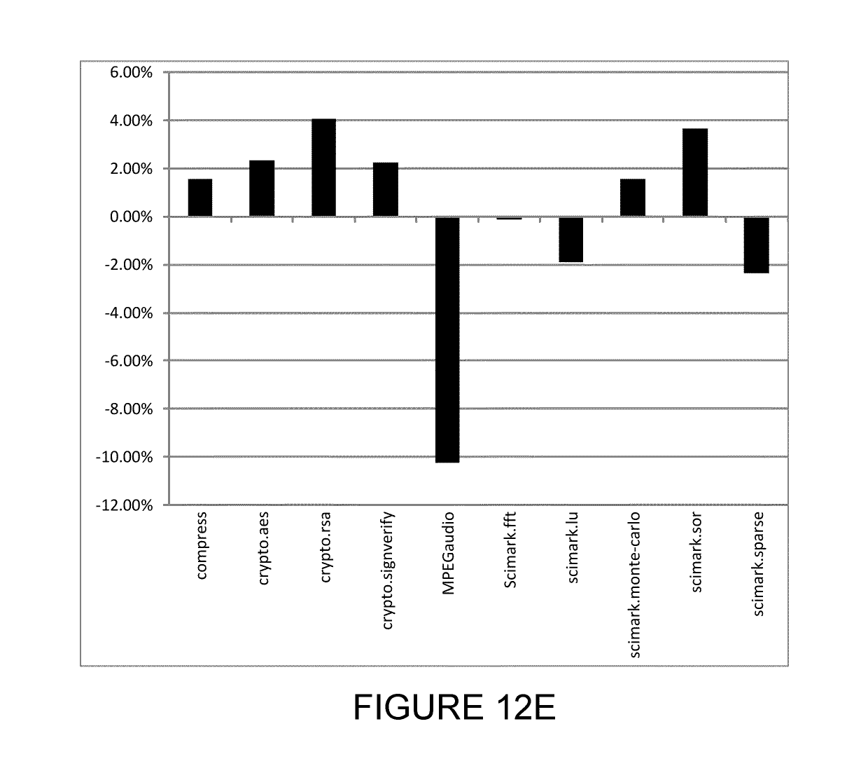

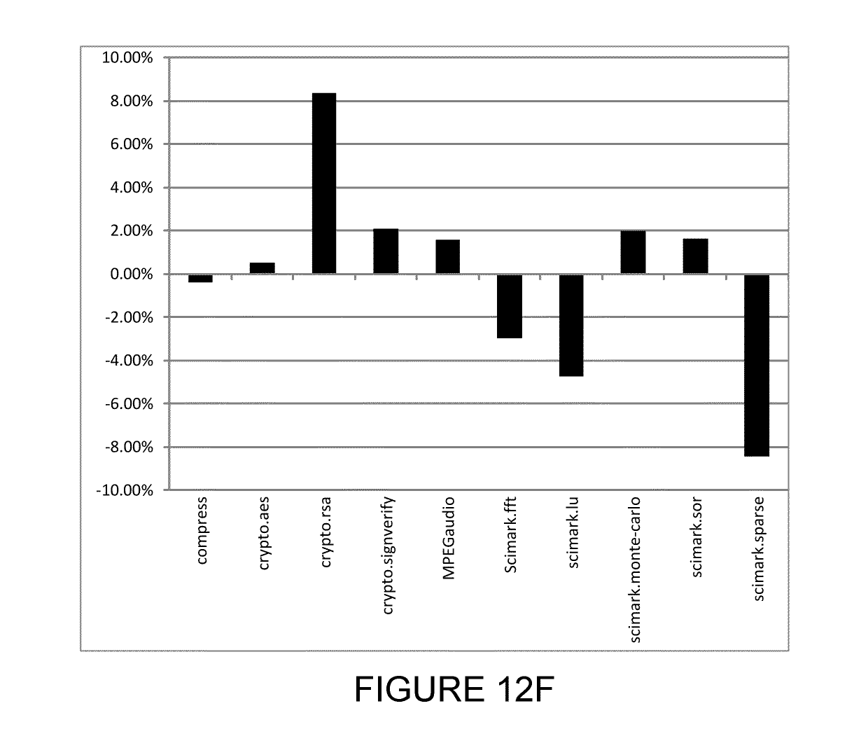

FIGS. 12A-12D show the percentage error of the power model using the HP AMD 6 computer system running ten (10) different benchmarks and using from 1 to 6 cores. The maximum and average absolute error rate is shown as 11.26% and 4.46% respectively for one to six cores. The values have small errors. The experiment results are summarized using processor frequencies of 2.00 GHz and 1.40 GHz in FIGS. 12E and 12F, respectively. The average error rate is 3.14%.

The software power analyzer 400 (see, e.g., FIG. 4) is a source code instrumentation technique that tracks power dissipation of each functional block of a software application. Two aspects of SPAN were monitored, the overhead and the responsiveness. Two benchmarks were used for testing. One benchmark is the FT benchmark from NAS parallel benchmark suite and the other benchmark is a synthetic benchmark that is a combination of integer operation, PI calculation, prime calculation, and bubble sort. The overhead of instrumentation on both testing benchmarks is negligible.

The execution was measured with and without the SPAN instrumentation ten times for each benchmark. The differences in execution time were within 1% on average. The present invention provides low overhead for the following reasons. The instrumentation is at the source code function-level, which adds few interruptions during executions. The PMCs used in the model are limited to the minimum values, which further reduce the computation and communication cost of SPAN. The power dissipation of the benchmarks was measured with and without underneath SPAN threads that record counter values. The overall variance across the whole execution was within 2% for ten valid runs. Considering other factors, such as temperature and power supply variation, 2% is a reasonable range.

Though there is no standard method to evaluate the responsiveness of a power model, one example can compare the continuous measured and estimated power values. Two multi-meters were used to measure the power used or dissipated by the target computer. Data from the multi-meters were stored in another assistant computer in intervals of one second. The benchmarks were executed on the Asus intel 4 platform with the SPAN source code instrumentation to estimate the power used by the target computer system.

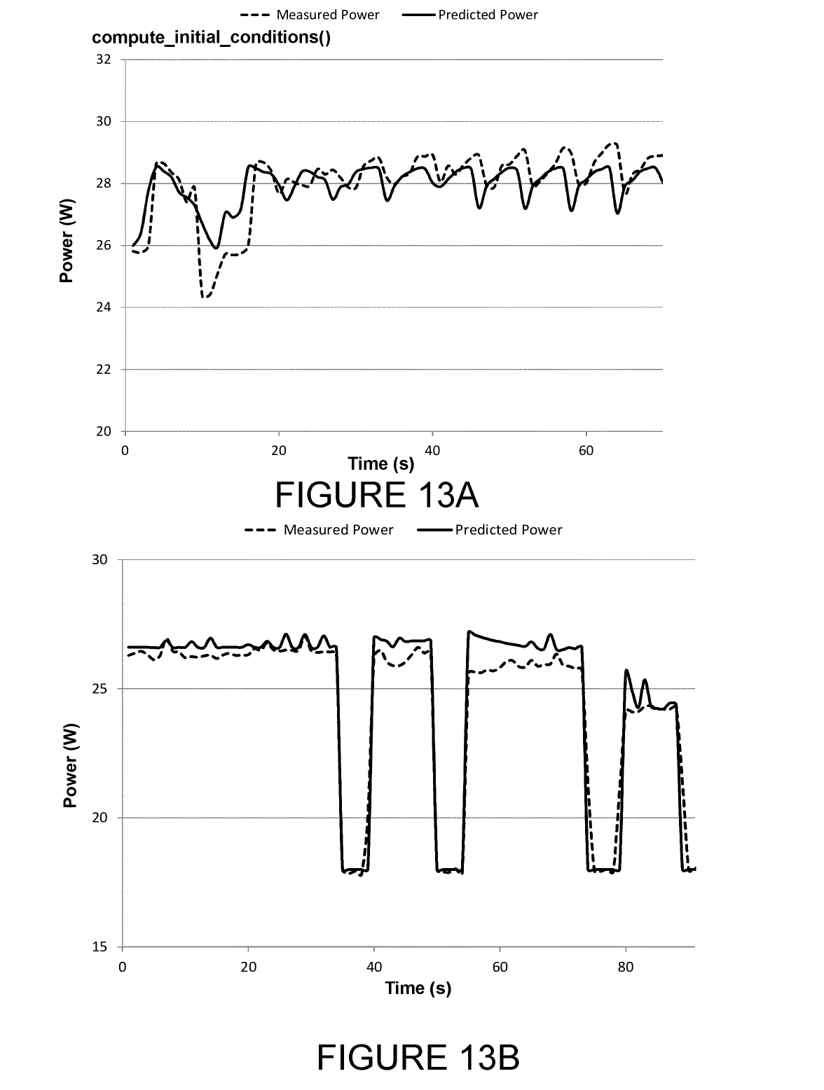

FIG. 13A shows a graph of power versus time for both measured power and estimated or modelled power for the FT benchmark. FIG. 13B shows a graph of power versus time for both measured power and estimated or modelled power for the synthetic benchmark. The graphs of FIGS. 13A and 13B demonstrate that the estimated power is closely related to the measured power dissipation at the overall shape. The first iteration of benchmark FT includes two functions, compute initial conditions( ) and fft( ). The rest iterations follow the same procedure in FIG. 13A. The estimations present a certain level of delay due to the rapid function changes in the source code. In FIG. 13B, insert sleep( ) functions were inserted between each sub benchmark in the synthetic workload in order to distinguish each one of them easily. The error rate is as low as 2.34% for both benchmarks on average.

The inventors of the present application have found that understanding the power dissipation behavior of a specific software/application, using methods and systems described herein, can lead to development of power-efficient software and assist in the design of energy efficient computer systems. The inventors further recognized the need for more accurate method to determine the power usage and dissipation of computer systems. Accordingly, the methods and systems described herein may provide a more accurate model and process to capture the power dissipation of computer systems.

It is believed that the present embodiments can provide an advantage over other ways to estimate power dissipation, e.g., cycle-level system simulators, instruction-level modeling, software-function-level macro-modeling, and PMCs based modeling. Software, when executed on a computer system, contributes considerably to the total power used by a computer system. Therefore, it can be important to find out how much power has been used or dissipated by a specific software component in order to design sustainable computer systems.

Power dissipation may be considered a fundamental aspect of software (e.g., instructions operating on a processor). The total energy consumption of completing a task is power accumulation over time. Power use or dissipation is a direct contributor to producing an energy profile. In some examples, controlling power dissipation provides more flexibility for computer system design. For example, the temperature with a computer enclosure can be altered by restricting power dissipation.

Some infrastructures include a “power envelope” as one of the design constraints. Large data centers maintain an overall power budget under a certain limit for power supply protection to prevent large current draws that can damage electronic components. Software designers and developers can use power modeling of power dissipation of a software application and the associated source code to design software that uses less energy and promotes sustainable computing.

One or more of the embodiments described herein can use run-time factors that determine the power dissipation of processors for computation intensive workloads on computer systems, including power-aware, multi-core computer systems. The embodiments described herein may include a two-level power model for power-aware multi-core computer systems. The number of performance counters and training benchmarks utilized in the present systems and methods can be minimized. Additionally, frequency of the hardware can be used in the present systems and methods to calculate power usage. A software developer can use software (instruction) power analysis to relate power dissipation to specific portions of an application source code and identify the sections of code that consume the most power in the program.

Aspects of the embodiments may be implemented in the general context of computer-executable instructions, such as program modules, being executed by a computer. Generally, program modules include routines, programs, objects, components, data structures, etc. that perform particular tasks or implement particular abstract data types. Aspects of the embodiments may also be practiced in distributed computing environments where tasks are performed by remote processing devices that are linked through a communications network. In a distributed computing environment, program modules may be located in both local and remote computer storage media including memory storage devices.

The present systems and methods can be used to assist in making computing devices more environmentally friendly by optimizing machine executable instructions to reduce the energy consumption and, hence, reduce the need to dissipate the heat generated by executing the instructions.

Thus, methods and systems for population of an application have been described. Although the present invention has been described with reference to specific example embodiments, it will be evident that various modifications and changes may be made to these embodiments without departing from the broader spirit and scope of the invention. Accordingly, the specification and drawings are to be regarded in an illustrative rather than a restrictive sense.

The present disclosure is related to the paper titled “SPAN: A software power analyzer for multicore computer systems,” by Shinan Wang, Hui Chen and Weisong Shi, published in Sustainable Computing: Informatics and Systems 1 (2011) 23-34, which document is hereby incorporated by reference for any purpose.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. A method for determining processor power, the method comprising:
determining at least one performance monitoring counter value for at least one processor;
determining a frequency of operation for the at least one processor;
calculating a processor power dissipation level for the at least one processor using a computing device; and
providing the processor power dissipation level as an output.

2. The method of claim 1, further comprising receiving at least one application programming interface.

3. The method of claim 1, further comprising running at least one of: at least one application or at least one thread.

4. The method of claim 1, further comprising generating a default file, the default file containing at least one power model parameter and at least one estimated frequency of operation.

5. The method of claim 1, further comprising generating a plurality of performance monitoring counter values for at least one core in a multi-core processor.

6. The method of claim 1, further comprising executing a software power analyzer control thread.

7. The method of claim 1, wherein determining at least one performance monitoring counter value includes determining instructions per cycle (IPC) for the at least one processor.

8. The method of claim 1, wherein calculating a processor power dissipation level for the at least one processor using a computing device includes calculating a processor power dissipation level for a function of the at least one processor using a computing device.

9. A machine-readable medium comprising instructions, which when implemented by a computer, cause the computer to perform the following operations:
determine at least one performance monitoring counter value for at least one processor;
determine a frequency of operation for the at least one processor;
calculate a power dissipation level for the at least one processor using a computing device; and
provide the power dissipation level as an output.

10. The medium of claim 9, wherein the instructions when implemented further cause the computer to receive at least one application programming interface.

11. The medium of claim 9, wherein the instructions when implemented further cause the computer to run at least one of: at least one application or at least one thread.

12. The medium of claim 9, wherein the instructions when implemented further cause the computer to generate a default file, the default file containing at least one power model parameter and at least one estimated frequency of operation.

13. The medium of claim 9, wherein the instructions when implemented further cause the computer to generate a plurality of performance monitoring counter values for at least one core in a multi-core processor.

14. The medium of claim 9, wherein the instructions when implemented further cause the computer to execute a software power analyzer control thread.

15. A system comprising:
at least one subsystem to determine at least one performance monitoring counter value for at least one processor;
at least one subsystem to determine a frequency of operation for the at least one processor;
at least one subsystem to calculate a processor power dissipation level for the at least one processor using a computing device; and
at least one subsystem to provide the processor power dissipation level as an output.

16. The system of claim 15, further comprising at least one subsystem to receive at least one application programming interface.

17. The system of claim 15, further comprising at least one subsystem to run at least one of: one application or one thread.

18. The system of claim 15, further comprising at least one subsystem to generate a default file, the default file containing at least one power model parameter and at least one estimated frequency of operation.

19. The system of claim 15, further comprising at least one subsystem to generate a plurality of performance monitoring counter values for at least one core in a multi-core processor.

20. The system of claim 15, further comprising at least one subsystem to generate executing a software power analyzer control thread.
